(19) United States
(12) Patent Application Publication
(10) Pub. No.: US 2026/0243521 A1
(43) Pub. Date: Aug. 20, 2026

(54) MODULAR HEAT SINK

(71) Applicant: Aivres Systems Inc., San Jose, CA (US)

(72) Inventor: Chao Chi Shih, Taipei (TW)

(21) Appl. No.: 19/058,804

(22) Filed: Feb. 20, 2025

(51) Int. Cl. F28F 3/04; H05K 7/20

(52) U.S. Cl. CPC F28F 3/04; H05K 7/20409; F28F 2215/00

(57) ABSTRACT

Disclosed herein is a modular heat sink including a first heat sink module and second heat sink module. The first heat sink module includes a first heat pipe, a first set of fins attached to the first heat pipe, and a base attached to the first heat pipe. The second heat sink module includes a second heat pipe and a second set of fins attached to the second heat pipe. The first heat pipe is connected to the second heat pipe.

### TECHNICAL FIELD

This disclosure is generally related to a modular heat sink for use with heat-generating electronic components.

### BACKGROUND

Air-cooled heat sinks or radiators as currently used in computer servers are fairly bulky in size, and even bulkier heat sinks are needed in order to increase their surface area for heat dissipation. As the dimensions of heat sinks increase, internal heat conduction within the heat sinks becomes less efficient, and it is necessary to use highly efficiency heat transfer devices to promote internal heat conduction. Such heat transfer devices include heat pipes, vapor chambers, and loop heat pipes. These heat transfer devices are generally only available in certain fixed sizes. Therefore, when a heat sink of a higher capacity is needed, it is usually necessary to manufacture, at substantial costs, a larger heat sink with a heat transfer device of the next available size. In other words, once a heat sink is made, it is not possible to expand its heat dissipation capacity.

The bulkiness of current heat sinks makes it important to consider their sizes and shapes when assembling computer server systems. Usually, server components and their heat sinks need to be installed in a particular order. For example, if there are electronic components underneath a large heat sink in a server chassis, the heat sink must be installed later when assembling the server. When service is required, the heat sinks must be removed before the electronic components below it can be repaired. Therefore, when designing computer systems, it is preferred to not place any heat sink in the space above any components that may need service, and this results in precious space in server chassis being wasted.

The modular heat sink disclosed herein affords more flexibility in assembling servers and uses chassis space more efficiently. Furthermore, its modular nature enables more rapid design and manufacture of heat sinks at lower costs.

### SUMMARY

Described herein is a modular heat sink for use in computer servers.

In one general aspect, disclosed herein a modular heat sink comprising a first heat sink module and second heat sink module. In some embodiments, the first heat sink module comprises a first heat pipe, a first set of fins attached to the first heat pipe, and a base attached to the first heat pipe. In some embodiments, the second heat sink module comprises a second heat pipe and a second set of fins attached to the second heat pipe. In some embodiments, the first heat pipe is connected to the second heat pipe.

In some embodiments, the base comprises a substantially flat region adapted for interfacing with a heat-generating electronic component.

In some embodiments, each of the first set of fins is substantially parallel to the base. In some embodiments, each of the first set of fins is substantially perpendicular to the first heat pipe. In some embodiments, each of the second set of fins is substantially perpendicular to the second heat pipe.

In some embodiments, the first heat pipe is fluidically connected to the second heat pipe via a pipe fitting. In some embodiments, the pipe fitting is a coupling fitting, an adapter fitting, a bushing fitting, a union fitting, or an elbow fitting.

In some embodiments, the pipe fitting is an elbow fitting, and the first heat pipe and the second heat pipe are connected at an angle between 0 and 180 degrees. In some embodiments, the angle is about 90 degrees. In some embodiments, the base, the first set of fins, and the second set of fins are not substantially colinear in space.

In some embodiments, the pipe fitting is a quick connect fitting.

In some embodiments, wherein the first heat pipe and the second heat pipe are rotatably connected. In some embodiments, the first heat pipe and the second heat pipe are connected via a swivel fitting.

In some embodiments, the modular heat sink further comprises a third heat sink module. In some embodiments, the third heat sink module comprises a third heat pipe and a third set of fins attached to the third heat pipe. In some embodiments, the third heat pipe is connected to the first heat pipe. In some embodiments, the third heat pipe is connected to the second heat pipe.

In another aspect, disclosed herein is a heat sink comprising a base having a substantially flat region adapted for interfacing with a heat-generating electronic component, a first heat pipe attached to the base, a first set of fins attached to the first heat pipe, a second heat pipe fluidically connected to the first heat pipe via a pipe fitting at an angle, and a second set of fins attached to the second heat pipe. In some embodiments, each of the first set of fins is substantially parallel to the base. In some embodiments, the second heat pipe is fluidically connected to the first heat pipe via a pipe fitting at an angle of about 90 degrees.

In yet another general aspect, disclosed herein is a computer system comprising a chassis, a printed circuit board disposed in the chassis and having a heat-generating electronic component, and a heat sink attached to the heat-generating electronic component. In some embodiments, the heat sink comprises a base having a substantially flat region adapted for interfacing with the heat-generating electronic component, a first heat pipe attached to the base, a first set of fins attached to the first heat pipe, a second heat pipe fluidically connected to the first heat pipe via a pipe fitting at an angle, and a second set of fins attached to the second heat pipe.

In some embodiments, the chassis is a rackmount chassis. In some embodiments, the printed circuit board is a motherboard. In some embodiments, the printed circuit board is a daughter board. In some embodiments, the printed circuit board is a GPU or coprocessor board.

In some embodiments, each of the first set of fins is substantially parallel to the base. In some embodiments, the second heat pipe fluidically connected to the first heat pipe via a pipe fitting at an angle of about 90 degrees.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 shows a modular heat sink including a first heat sink module and a second heat sink module.

FIG. 2 shows how the modular heat sink functions.

FIG. 3 illustrates the first heat sink module of the modular heat sink.

FIG. 4 illustrates the second heat sink module of the modular heat sink.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

The term “about” is used herein to mean approximately, in the region of, roughly, or around. When the term “about” is used in conjunction with a numerical range, it modifies that range by extending the boundaries above and below the numerical values set forth. In general, the term “about” or “approximately” is used herein to modify a numerical value above and below the stated value by a variance of 20%.

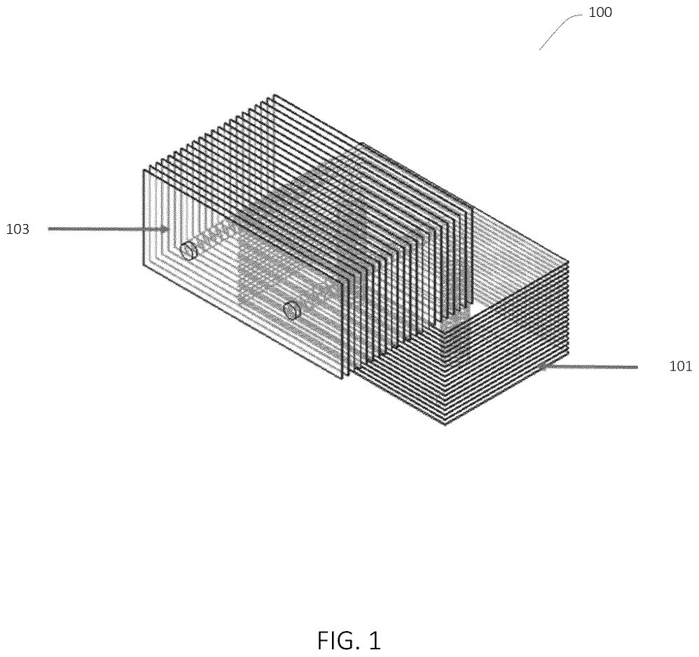

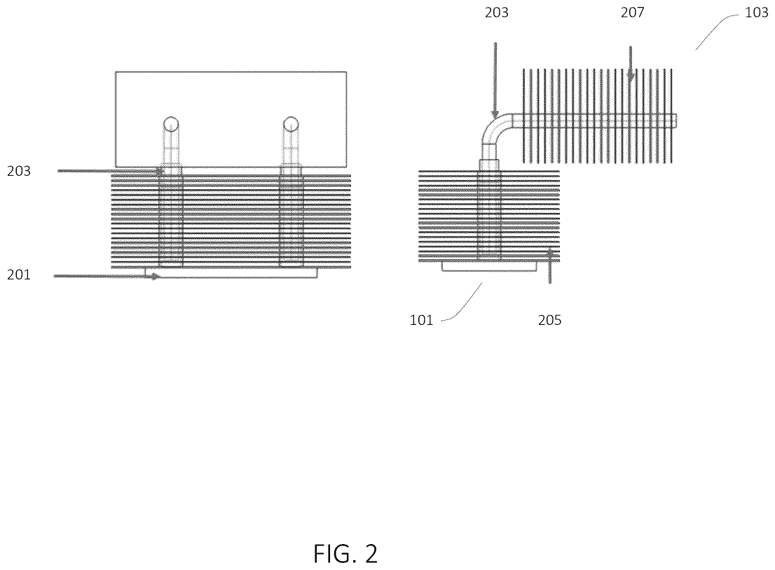

The embodiments will now be explained with the accompanying figures. Reference is first made to FIGS. 1 and 2, which show a modular heat sink 100. FIG. 1 shows a modular heat sink 100 comprising a first heat sink module 101 and second heat sink module 103. FIG. 2 shows a front view and a lateral view of the modular heat sink. The first heat sink module 101 comprises a first heat pipe, a first set of fins 205 attached to the first heat pipe, and a base 201 attached to the first heat pipe. The second heat sink module 103 comprises a second heat pipe and a second set of fins 207 attached to the second heat pipe. The first heat pipe is connected to the second heat pipe via a pipe fitting 203.

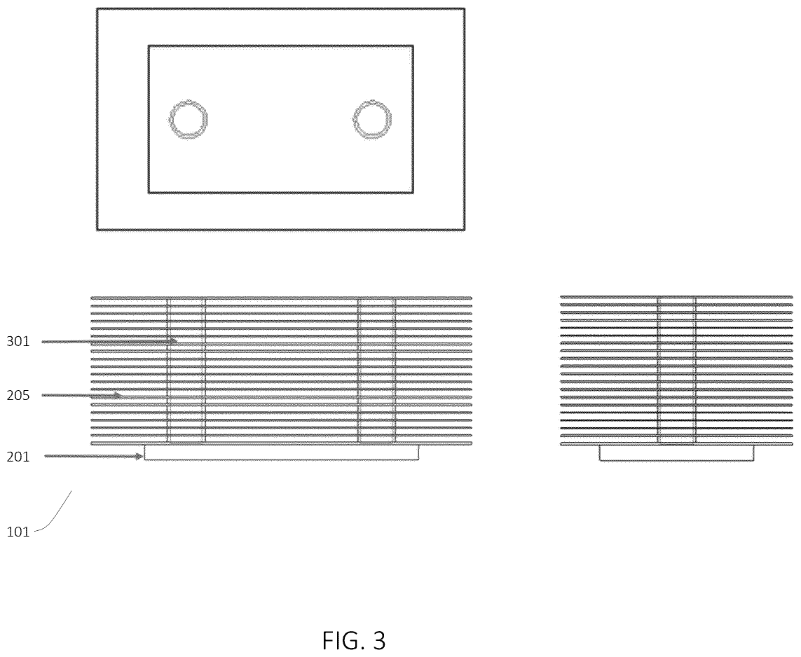

FIG. 3 illustrates the first heat sink module 101 of the modular heat sink. The first heat sink module 101 comprises a first heat pipe 301, a first set of fins 205 attached to the first heat pipe 301, and a base 201 attached to the first heat pipe 301.

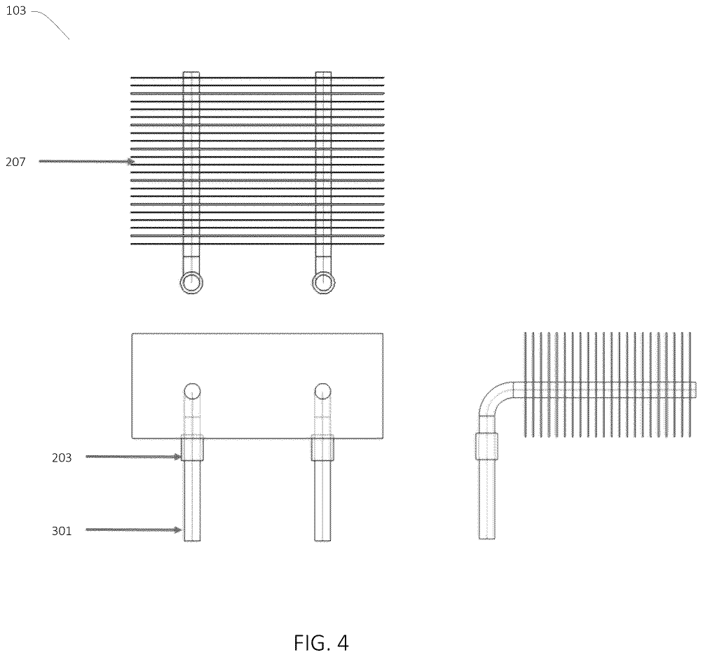

FIG. 4 illustrates the second heat sink module 103 of the modular heat sink. The second heat sink module 103 comprises a second heat pipe and a second set of fins 207 attached to the second heat pipe. The first heat pipe 301 is connected to the second heat pipe via a pipe fitting 203.

The base can be of any shape suitable to be attached to a heat-generating electronic component, such as, for example, an electronic component mounted to a printed circuit board (not shown). A heat-generating electronic component is any device that produces heat that is undesirable; most typically, the electronic component is a central processing unit (CPU) or a graphics processing unit (GPU), for example. The base is integral, i.e., formed as a continuous body of material that has a high propensity for conducting heat although the base may be formed in multiple attached pieces, i.e., non-integral.

The base can be formed from materials such as aluminum, copper, and/or other metal alloys, plastic and/or epoxy, and/or any other suitable heat conducting material. In one embodiment, the base is formed from a continuous piece of aluminum alloy and its bottom is shaped to fit the contour of one or more electronic components. In another embodiment, the base is formed from two different materials, such as for example, aluminum in a first region and copper in a second region. The two regions are attached together by a conventional means such as bolting or gluing with heat-conductive adhesive.

Each of the first heat sink module and the second heat sink module includes one or more heat pipes. A heat pipe is a vacuum-sealed pipe that is filled with a heat-transfer liquid, such as water, and has the interior wall of the heat pipe covered with a wicking material. As the electronic component heats up, the “hot” end of the heat pipe closest to the electronic component also heats up. The liquid near the hot end of the heat pipe eventually evaporates and the resultant vapor collects at the “cool” end of the heat pipe where the vapor then condenses. The condensed liquid flows back to the hot end of the heat pipe via wicking, and evaporating liquid again migrates to the cool end of the heat pipe. This evaporation/condensation cycle repeats as the heat pipe transfers heat efficiently such that the hot end of the heat pipe is kept at or near the same temperature as the cool end. Furthermore, because the boiling point of the fluid changes with the pressure, the pressure inside the heat pipe can be reduced such that boiling occurs at a desired temperature.

In some embodiments, the base is attached to a single heat pipe. In some embodiments, the base is attached to multiple heat pipes. In the embodiment shown in FIGS. 1 to 4, two heat pipes are attached to the base 201, each of which is a first heat pipe. The heat pipe can be attached to the base in any manner, including adhesive, form-fitted (“snap-on”), harnessed, bolted, etc.

Each of the first heat sink module and the second heat sink module includes a set of fins, which are intended to increase the surface area in order to promote convective heat dissipation to ambient air. By increasing the surface area in contact with the ambient air, heat is more effectively dissipated from the electronic component through the heat sink to the ambient air.

The fins can be attached to one or more heat pipes in a variety of manners. They are typically machined to form fit around the heat pipes, such that friction holds the fins in place and flange spacers are used to maintain space between the fins when assembled. Alternatively, the fins can be attached in other manners, such as by using adhesive or harnessing. In some embodiments the fins may be detachable from the heat sink.

The first heat pipe in the first heat sink module can be connected to the second heat pipe in the second heat sink module by a pipe fitting, such that a leakproof liquid connection is made between the heat pipes. A variety of pipe fittings can be used, such as a coupling fitting, an adapter fitting, a bushing fitting, a union fitting, or an elbow fitting. Pipe couplers slip over the outside of two pipes to connect them, usually permanently. A coupling can be a reducer, or a reducing coupling. This means they reduce flow by joining a larger pipe to a smaller size. Adapters are used when connecting two pipes of different types. For example, an adapter could be fitted on the end of a plain pipe to allow a threaded connection at the other side of the adapter. Bushings, sometimes called reducer bushings, are used for connecting two pipes of different sizes. The larger diameter of the bushing fits inside of the larger pipe. The smaller pipe is then inserted into the smaller end of the bushing. Unions are similar to couplings in that they connect two similar pipes. With pipe unions, a nut or threaded ring in the middle of the fitting is tightened to join two pipes. It can be easily removed by loosening the ring to disconnect the pipes. However, a coupling must be cut out to disconnect.

An elbow fitting can be used to connect the first heat pipe and the second heat pipe at an angle. Elbows change the direction of flow between two pipes. Common elbows have 90, 60, 45 and 22½ degree bends and are used to make a turn. They can be joined together to move around obstructions in the pipe run. In the embodiment shown in FIGS. 1 to 4, the first heat pipe and the second heat pipe are connected at a 90-degree angle, such that the base, the first set of fins, and the second set of fins are not aligned on a straight line.

In some embodiments, the first heat pipe in the first heat sink module is rotatably connected to the second heat pipe in the second heat sink module. For example, this may be accomplished by using a swivel fitting.

In some embodiments, the first heat pipe in the first heat sink module can be connected to the second heat pipe in the second heat sink module by a quick connect fitting. Quick connect fittings (also referred to as quick couplings) are connectors that join fluid lines. They are designed to be used without tools and connect with a simple push or twist. There are a variety of quick connect fittings that may be used. “Ball and sleeve” type quick connect fitting features a retractable sleeve that connects coupler halves. The male ball end fits into the female outer sleeve. For example, FloLok® Quick Connect is a type of ball and sleeve fitting. “Push to connect” is another type of quick connect fitting that working similarly to ball and sleeve connections. Push to connect fittings function by pushing one end into the other. To disconnect, a collar is retracted. “Cam-lock” is a type of quick connect fitting that uses foldable tabs on the female half to lock the receiver in place. “Luer lock” is a type of quick connect fitting that connects by twisting and is commonly used in syringes and needles. There are also twist or bayonet fittings that utilize a ⅛ to ¼ turn to connect and disconnect.

In some embodiments, the quick connect fittings are leak-free and/or dripless. In some embodiments, the quick connect fittings can be CPC™-brand or Everis®-brand liquid cooling quick disconnect couplings, such as Everis® LQ2, LQ4, LQ4S, LQ6, or LQ8.

Still referring to FIG. 2, when the base 201 at the bottom of the first heat sink module absorbs waste heat, the waste heat is transferred via conduction to a fluid inside the first heat pipe. This fluid mediates the transfer of heat in the first heat pipe. As the fluid is heated, it boils and becomes a vapor, and therefore transfers heat by convection. One end of the second heat pipe of the second heat sink is submerged in the fluid of the first heat pipe, and the heat from the fluid is then conducted to the second set of fins 207 of the second heat sink module.

The modular heat sinks according to the present disclosure can be re-used and re-assembled according to space constraints and thermal dissipation requirements in server systems of different configurations. The modular nature of the heat sinks also facilitates the assembly of server systems and can therefore be made larger than conventional heat sinks to make better use of the space available inside a server chassis.

The foregoing description of the present disclosure has been provided for the purposes of illustration and description. It is not intended to be exhaustive or to limit the disclosure to the precise forms disclosed. The breadth and scope of the present disclosure should not be limited by any of the above-described exemplary embodiments. Many modifications and variations will be apparent to the practitioner skilled in the art. The modifications and variations include any relevant combination of the disclosed features. The embodiments were chosen and described in order to best explain the principles of the disclosure and its practical application, thereby enabling others skilled in the art to understand the disclosure for various embodiments and with various modifications that are suited to the particular use contemplated. It is intended that the scope of the disclosure be defined by the following claims and their equivalence.

What is claimed is:

1. A modular heat sink comprising:
a first heat sink module and second heat sink module;
wherein the first heat sink module comprises a first heat pipe, a first set of fins attached to the first heat pipe, and a base attached to the first heat pipe;
wherein the second heat sink module comprises a second heat pipe and a second set of fins attached to the second heat pipe; and
wherein the first heat pipe is connected to the second heat pipe.

2. The modular heat sink of claim 1, wherein the base comprises a substantially flat region adapted for interfacing with a heat-generating electronic component.

3. The modular heat sink of claim 1, wherein each of the first set of fins is substantially parallel to the base.

4. The modular heat sink of claim 1, wherein each of the first set of fins is substantially perpendicular to the first heat pipe.

5. The modular heat sink of claim 1, wherein each of the second set of fins is substantially perpendicular to the second heat pipe.

6. The modular heat sink of claim 1, wherein the first heat pipe is fluidically connected to the second heat pipe via a pipe fitting.

7. The modular heat sink of claim 6, wherein the pipe fitting is a coupling fitting, an adapter fitting, a bushing fitting, a union fitting, or an elbow fitting.

8. The modular heat sink of claim 6, wherein the pipe fitting is an elbow fitting, and the first heat pipe and the second heat pipe are connected at an angle between 0 and 180 degrees.

9. The modular heat sink of claim 8, wherein the angle is about 90 degrees.

10. The modular heat sink of claim 1, wherein the base, the first set of fins, and the second set of fins are not substantially colinear in space.

11. The modular heat sink of claim 6, wherein the pipe fitting is a quick connect fitting.

12. The modular heat sink of claim 1, wherein the first heat pipe and the second heat pipe are rotatably connected.

13. The modular heat sink of claim 11, wherein the first heat pipe and the second heat pipe are connected via a swivel fitting.

14. The modular heat sink of claim 1, further comprising a third heat sink module; wherein the third heat sink module comprises a third heat pipe and a third set of fins attached to the third heat pipe; and wherein the third heat pipe is connected to the first heat pipe or the second heat pipe.

15. A heat sink comprising:
a base having a substantially flat region adapted for interfacing with a heat-generating electronic component,
a first heat pipe attached to the base,
a first set of fins attached to the first heat pipe, wherein each of the first set of fins is substantially parallel to the base,
a second heat pipe fluidically connected to the first heat pipe via a pipe fitting at an angle, and
a second set of fins attached to the second heat pipe.

16. The heat sink of claim 15, wherein the angle is about 90 degrees.

17. A computer system comprising:
a chassis,
a printed circuit board disposed in the chassis and having a heat-generating electronic component, and
a heat sink attached to the heat-generating electronic component; and
wherein the heat sink comprises:
a base having a substantially flat region adapted for interfacing with the heat-generating electronic component,
a first heat pipe attached to the base,
a first set of fins attached to the first heat pipe, wherein each of the first set of fins is substantially parallel to the base,
a second heat pipe fluidically connected to the first heat pipe via a pipe fitting at an angle, and
a second set of fins attached to the second heat pipe.

18. The computer system of claim 17, wherein the chassis is a rackmount chassis.

19. The computer system of claim 17, wherein the printed circuit board is a motherboard or a GPU/coprocessor board.

20. The computer system of claim 17, wherein the heat-generating electronic component is a CPU, a GPU, or a coprocessor.
